(19) United States
(12) Patent Application Publication
(10) Pub. No.: US 2015/0364626 A1
(43) Pub. Date: Dec. 17, 2015

(54) TRANSPARENT ELECTRODE AND SOLAR CELL INCLUDING THE SAME

(71) Applicant: Electronics and Telecommunications Research Institute, Daejeon (KR)

(72) Inventor: JungWook LIM, Daejeon (KR)

(73) Assignee: Electronics and Telecommunications Research Institute, Daejeon (KR)

(21) Appl. No.: 14/709,524

(22) Filed: May 12, 2015

(30) Foreign Application Priority Data
Jun. 11, 2014 (KR) 10-2014-0071006
Dec. 26, 2014 (KR) 10-2014-0190604

(51) Int. Cl. H01L 31/0224

(52) U.S. Cl. CPC H01L 31/022466; H01L 31/022425

(57) ABSTRACT

The present invention relates to a low-discharge transparent electrode and a solar cell including the same. The transparent electrode includes a first dielectric layer and a multi-layered metal layer stacked on a substrate. The multi-layered metal layer includes a main metal layer and a bridge metal layer. The main metal layer has an uneven surface, and the bridge metal layer covers the uneven surface of the main metal layer. A sheet resistance of the multi-layered metal layer is smaller than that of the main metal layer.

### CROSS-REFERENCE TO RELATED APPLICATIONS

This U.S. non-provisional patent application claims priority under 35 U.S.C. §119 of Korean Patent Application Nos. 10-2014-0071006, filed on Jun. 11, 2014, and 10-2014-0190604, filed on Dec. 26, 2014, the entire contents of which are hereby incorporated by reference.

### BACKGROUND OF THE INVENTION

The present invention relates to a low-discharge transparent electrode and a solar cell including the same.

In large cities with high population density, electric power is mostly consumed by buildings. Recently, a zero-energy building capable of producing and saving energy from environment-friendly energy sources has become an issue. A solar cell receives an attention as a power source of zero energy. In particular, as buildings with large windows and doors are increased, it is required to develop and produce transparent solar cells for windows and doors which are able to generate electricity while having excellent transmissivity and visibility.

It has become mandatory to adopt low-emissivity glass (low-discharge glass) for blocking infrared light to save energy of a building, and at least half of all buildings have adopted such glass in Europe. One of current technical issues is to improve insulating properties of glass and selectivity with respect to transmission/cutoff of visible light and infrared light.

Researches on transparent solar cells have particularly focused on dye-sensitized solar cells and organic solar cells. However, the dye-sensitized solar cells is not free from electrolyte leakage, are limited in improvement of durability, and are not efficient for a large area, causing difficulty in terms of mass production. Regarding the organic solar cells, it is still difficult to commercialize such solar cells due to limitation in terms of durability and characteristics thereof. Recently, a full-transmission-type transparent solar cell has been developed instead of an aperture-type silicon thin-film solar cell. It has been reported that such a solar cell allows color implementation and has excellent durability, indicating the feasibility of using such a solar cell in windows and doors.

### SUMMARY OF THE INVENTION

The present invention provides a transparent electrode having excellent optical characteristics and a low sheet resistance.

The present invention also provides a solar cell having a high transmissivity of visual light.

Embodiments of the present invention provide transparent electrodes including a first dielectric layer and a multi-layered metal layer stacked on a substrate, wherein the multi-layered metal layer includes a main metal layer and a bridge metal layer, wherein the main metal layer has an uneven surface, wherein the bridge metal layer covers the uneven surface of the main metal layer and has a top surface that is more even than the uneven surface of the main metal layer, wherein a sheet resistance of the multi-layered metal layer is smaller than that of the main metal layer.

In some embodiments, the main metal layer may include a recess region in the uneven surface, wherein the bridge metal layer may fill the recess region.

In other embodiments, a distance between a bottom surface of the recess region and a bottom surface of the main metal layer may be smaller than an average thickness of the main metal layer.

In still other embodiments, the sheet resistance of the multi-layered metal layer may be from about 1 Ω/□ to about 2000 Ω/□.

In even other embodiments, a thickness of the main metal layer may be from about 1 nm to about 50 nm, and a thickness of the main metal layer may be from about 0.1 nm to about 15 nm.

In yet other embodiments, the main metal layer and the bridge metal layer may include different metal materials, wherein the main metal layer may include Ag, Cu, Au, Pt or Al, wherein the bridge metal layer may include Ag, Cu, Al, Au, Pt, Cr, Ni, Zn or Zr.

In further embodiments, the transparent electrode may further include a second dielectric layer on the multi-layered metal layer, wherein the first and second dielectric layers may individually include ZnO, Al₂O₃, V₂O₅, TiO₂, SiO₂, SiN, ZrO₂, ITO, ZnO:Al, ZnO:Ga, ZnO:B, or SnO₂.

In still further embodiments, a thickness of the first dielectric layer may be from about 0.1 nm to about 500 nm.

In even further embodiments, the multi-layered metal layer further may include an optical metal layer spaced apart from the bridge metal layer with the main metal layer interposed therebetween, wherein a cutoff wavelength of the multi-layered metal layer may be larger than that of a double layer including the main metal layer and the bridge metal layer, wherein the cutoff wavelength may be a wavelength of an infrared region at which an optical transmissivity of a layer is reduced to about 30% or lower.

In yet further embodiments, the main metal layer and the optical metal layer may include different metal materials, wherein the optical metal layer may include Ag, Cu, Al, Au, Pt, Cr, Ni, Zn or Zr.

In much further embodiments, a thickness of the optical metal layer may be from about 0.1 nm to about 50 nm.

In still much further embodiments, the transparent electrode may further include a cutoff wavelength control layer disposed between the first dielectric layer and the multi-layered metal layer, the cutoff wavelength control layer changing a cutoff wavelength of the transparent electrode, wherein the cutoff wavelength may be a wavelength of an infrared region at which an optical transmissivity of a layer is reduced to about 30% or lower, wherein a refractive index of the cutoff wavelength control layer may be different from refractive indices of the first dielectric layer and the multi-layered metal layer.

In even much further embodiments, the cutoff wavelength control layer may shift the cutoff wavelength of the transparent electrode to a large wavelength.

In yet much further embodiments, the cutoff wavelength control layer may include a metal selected from the group consisting of Ag, Cu, Al, Au, Pt, Cr, Ni, Zn and Zr or a dielectric material selected from the group consisting of ZnO, ITO, Al₂O₃, V₂O₅, TiO₂, SiO₂, SiN and ZrO₂.

In yet still much further embodiments, a thickness of the cutoff wavelength control layer may be from about 0.1 nm to about 50 nm.

In yet even much further embodiments, the cutoff wavelength of the transparent electrode may be from about 3 μm to about 10 μm.

In other embodiments of the present invention, transparent electrodes include a first dielectric layer and a multi-layered metal layer stacked on a substrate, wherein the multi-layered metal layer includes a main metal layer and a bridge metal layer stacked to directly contact each other, wherein the main metal layer and the bridge metal layer have different refractive indices, wherein a transmissivity of visual light with a wavelength of from about 400 nm to about 800 nm of the multi-layered metal layer is larger than that of the main metal layer.

In some embodiments, the main metal layer may include an uneven surface and a recess region formed therein, wherein the bridge metal layer may fill the recess region.

In other embodiments, the multi-layered metal layer further may include an optical metal layer spaced apart from the bridge metal layer with the main metal layer interposed therebetween, wherein the bridge metal layer, the main metal layer, and the optical metal layer may have different refractive indices, wherein a cutoff wavelength of the multi-layered metal layer may be larger than that of a double layer including the main metal layer and the bridge metal layer, wherein the cutoff wavelength may be a wavelength of an infrared region at which an optical transmissivity of a layer is reduced to about 30% or lower.

In still other embodiments of the present invention, solar cells include a first electrode and a second electrode on a substrate, and an optical absorption layer disposed between the first electrode and the second electrode, wherein at least one of the first electrode and the second electrode is a transparent electrode, wherein the transparent electrode includes a first dielectric layer and a multi-layered metal layer stacked, wherein the multi-layered metal layer includes a main metal layer and a bridge metal layer, wherein the main metal layer includes an uneven surface, wherein the bridge metal layer covers the uneven surface of the main metal layer and has a top surface that is more even than the uneven surface of the main metal layer, wherein a sheet resistance of the multi-layered metal layer is smaller than that of the main metal layer.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view illustrating a transparent electrode according to an embodiment of the present invention;

FIG. 2 is an enlarged view of the part T of FIG. 1;

FIG. 3 is a cross-sectional view illustrating a transparent electrode according to another embodiment of the present invention;

FIG. 4 is a cross-sectional view illustrating a transparent electrode according to still another embodiment of the present invention;

FIG. 5 is a graph illustrating a change of a cutoff wavelength of the transparent electrode in the embodiments of the present invention;

FIG. 6 is a conceptual diagram illustrating that the transparent electrode enables directivity control with respect to transmission/cutoff of infrared light;

FIG. 7 is a cross-sectional view illustrating a solar cell according to an embodiment of the present invention; and

FIG. 8 is a cross-sectional view illustrating a solar cell according to another embodiment of the present invention.

FIG. 9 is a conceptual diagram illustrating a function of a solar cell provided with the transparent electrode in the embodiments of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In this description, when an element is referred to as being ‘on’ another element, it can be directly on the other element, or intervening elements may also be present. In the drawings, the dimensions of elements are exaggerated for clarity of illustration. Like reference numerals refer to like elements throughout.

The embodiments of the present invention will be described with reference to exemplary cross-sectional view and/or planar views. In the drawings, the dimensions of layers and regions are exaggerated for clarity of illustration. Therefore, the regions illustrated in the drawings are merely schematic, and the shapes of the regions exemplify specific shapes of the elements but do not limit the scope of the invention. Relational terms such as “first”, “second”, “third”, and the like are used in various embodiments of the present invention to describe various elements, but the elements should not be limited by the terms. Such terms are merely used to distinguish one element from another element. The embodiments described herein include complementary embodiments thereof.

The terminology used herein is not for delimiting the embodiments of the present invention but for describing the embodiments. The terms of a singular form may include plural forms unless otherwise specified. The term “include”, “including”, “comprise” and/or “comprising” used herein does not exclude existence or addition of one or more other elements besides mentioned elements.

### Embodiment 1

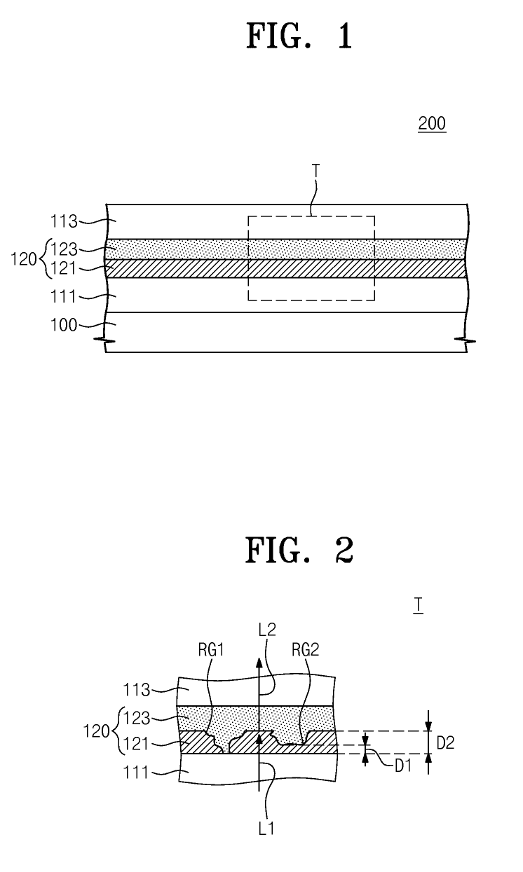

FIG. 1 is a cross-sectional view illustrating a transparent electrode 200 according to an embodiment of the present invention.

Referring to FIG. 1, a first dielectric layer 111, a multi-layered metal layer 120, and a second dielectric layer 113 may be sequentially stacked on a substrate 100. The multi-layered metal layer 120 may be disposed between the first and second dielectric layers 111 and 113. The multi-layered metal layer 120 may include a main metal layer 121 and a bridge metal layer 123. One surface of the main metal layer 121 may directly contact one surface of the bridge metal layer 123. Another surface of the main metal layer 121 may directly contact the first dielectric layer 111, and another surface of the bridge metal layer 123 may directly contact the second dielectric layer 113.

The substrate 100 may be a transparent substrate, and may include, for example, glass, polyether sulfone (PES), polyethylene naphthalene (PEN), polyethylene terephthalate (PET), polyimide (PI), or acrylic resin, but is not limited thereto.

A thickness of the first dielectric layer 111 may be from about 0.1 nm to about 500 nm. The first dielectric layer 111 may include ZnO, Al₂O₃, V₂O₅, TiO₂, SiO₂, SiN, ZrO2, ITO, ZnO:Al, ZnO:Ga, ZnO:B, or SnO₂. The above description of the thickness and material of the first dielectric layer 111 may be the same as that of the second dielectric layer 113.

FIG. 2 is an enlarged view of the part T of FIG. 1.

Referring to FIG. 2, the main metal layer 121 on the first dielectric layer 111 may have an uneven surface. That is, since the main metal layer 121 is formed to a small thickness to increase optical transmissivity, a surface of the main metal layer 121 may be uneven. Furthermore, the main metal layer 121 may be grown to an island structure, so that the surface of the main metal layer 121 may not be uneven and may be discontinuous.

For example, the main metal layer 121 may include first and second recess regions RG1 and RG2. The first recess region RG1 may pass through the main metal layer 121. Therefore, parts of the main metal layer 121 adjacent to the first recess region RG1 may be separated from each other. The first recess region RG1 may increase a sheet resistance of the main metal layer 121, causing degradation of electrical characteristics of the transparent electrode 200.

The second recess region RG2 may be dented from a top surface of the main metal layer 121 towards a bottom surface thereof. A thickness between a bottom surface of the second recess region RG2 and the bottom surface of the main metal layer 121 may be a first thickness D1. An average thickness of the main metal layer 121 may be a second thickness D2. Here, the second thickness D2 may be larger than the first thickness D1. Since the first thickness D1 is smaller than the second thickness D2, the second recess region RG2 may increase the sheet resistance of the main metal layer 121, causing the degradation of the electrical characteristics of the transparent electrode 200.

The second thickness D2 may be decreased so that the main metal layer 121 transmits light, to achieve the transparent electrode 200. That is, if the second thickness D2 of the main metal layer 121 is too large, the sheet resistance of the main metal layer 121 is decreased, but transmissivity of visual light of the main metal layer 121 is reduced, hindering the transparent electrode 200 from exhibiting a function thereof. On the contrary, if the second thickness D2 of the main metal layer 121 is small (for example, about 20 nm or less), the first and second recess regions RG1 and RG2 may greatly affect and increase the sheet resistance of the main metal layer 121.

The bridge metal layer 123 may be provided on the main metal layer 121 to cover the uneven surface of the main metal layer 121. That is, the bridge metal layer 123 may fill the first and second recess regions RG1 and RG2. Accordingly, the bridge metal layer 123 may provide an additional electric connection passage to the main metal layer 121, thereby reducing the sheet resistance increased due to the first and second recess regions RG1 and RG2. A metal layer that has a higher sheet resistance than that of the main metal layer 121 but has a better optical transmission characteristic than that of the main metal layer 121 may be used as the bridge metal layer 123. Therefore, in the case where the second thickness D2 of the main metal layer 121 is small (for example, about 20 nm or less), the bridge metal layer 123 may increase the transmissivity of visual light of the multi-layered metal layer 120 while reducing the sheet resistance of the multi-layered metal layer 120. For example, the transmissivity of visual light with a wavelength of from about 400 nm to about 800 nm of the multi-layered metal layer 120 may be higher than that of the main metal layer 121. The sheet resistance of the multi-layered metal layer 120 may be from about 1 Ω/□ to about 2000 Ω/□. Furthermore, the top surface of the bridge metal layer 123 may be more even than that of the main metal layer 121.

The second thickness D2 of the main metal layer 121 may be from about 1 nm to about 50 nm. If the second thickness D2 is larger than about 50 nm, the transmissivity of visual light may be greatly reduced, hindering the transparent electrode 200 from exhibiting a function thereof. On the contrary, if the second thickness D2 is smaller than about 1 nm, the sheet resistance of the multi-layered metal layer 120 may be increased, degrading the electrical characteristics of the transparent electrode 200. An average thickness of the bridge metal layer 123 may be from about 0.1 nm to about 15 nm.

The main metal layer 121 and the bridge metal layer 123 may include different metal materials. The main metal layer 121 may include Ag, Cu, Au, Pt or Al. The bridge metal layer 123 may include Ag, Cu, Al, Au, Pt, Cr, Ni, Zn or Zr.

A first light L1 may be incident to the first dielectric layer 111. Here, the first light L1 that has passed through the multi-layered metal layer 120 may be emitted as a second light L2 through the second dielectric layer 113. The second light L2 may have a different wavelength range from that of the first light L1. The change from the first light L1 into the second light L2 may be determined by optical transmissivity of the multi-layered metal layer 120.

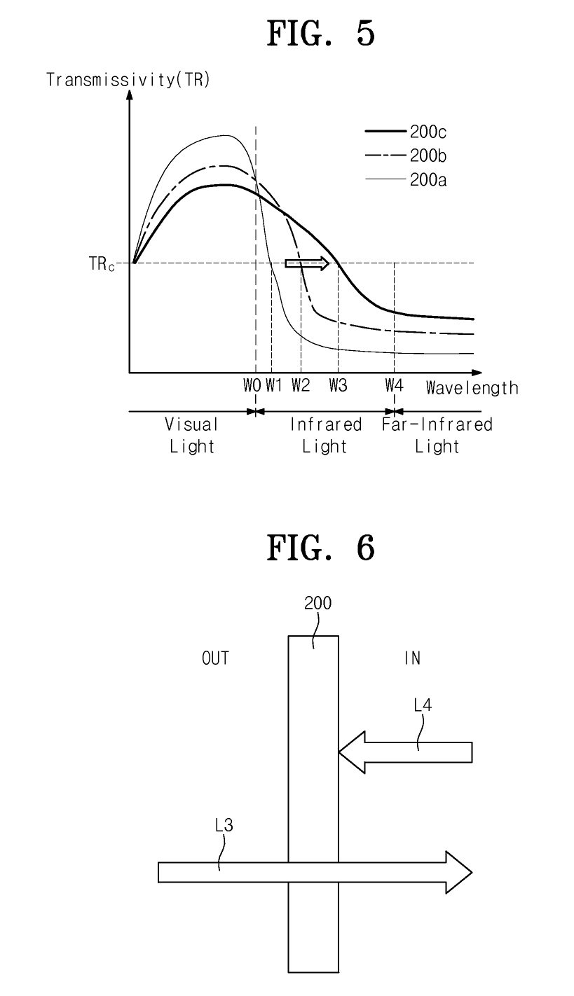

The main metal layer 121 and the bridge metal layer 123 may have different refractive indices. Therefore, the difference in refractive index between the main metal layer 121 and the bridge metal layer 123 may cause an optical interference effect. The optical transmissivity of the multi-layered metal layer 120 may be changed due to optical interference on an interface between the main metal layer 121 and the bridge metal layer 123. That is, the optical transmissivity may be decreased or increased at a specific optical wavelength range (see FIG. 5). This indicates that the second light L2 may be changed according to whether the bridge metal layer 123 exists.

As described above, according to the present embodiment, the metal materials of the main metal layer 121 and the bridge metal layer 123 and/or the thicknesses of the main metal layer 121 and the bridge metal layer 123 are adjusted so that the transmissivity of visual right or infrared light of a specific wavelength range may be increased. Furthermore, the sheet resistance of the multi-layered metal layer 120 may be reduced while increasing the optical transmissivity of the multi-layered metal layer 120.

### Embodiment 2

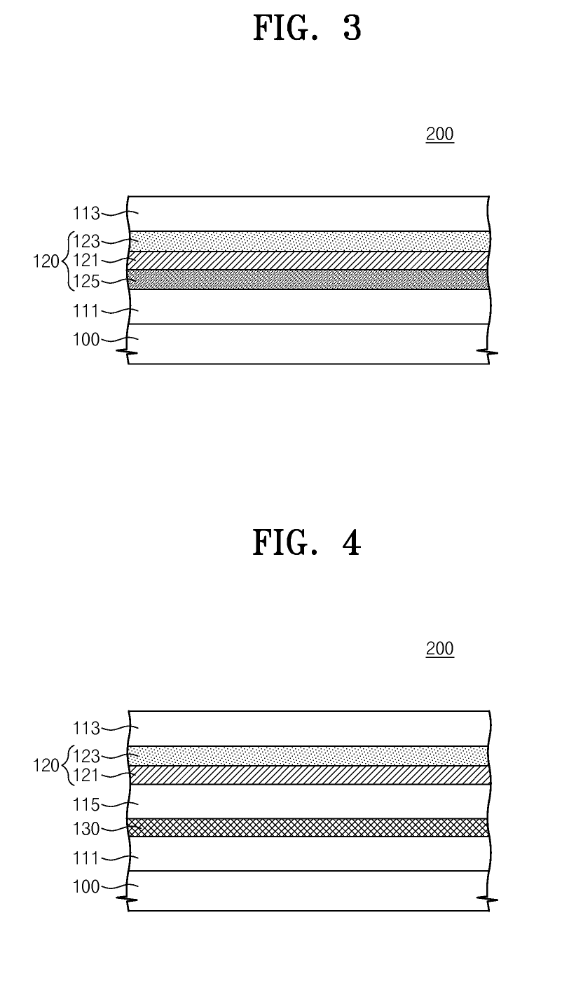

FIG. 3 is a cross-sectional view illustrating a transparent electrode 200 according to another embodiment of the present invention. Regarding the present embodiment, detailed descriptions on technical features that overlap with those described above with reference to FIGS. 1 and 2 are not provided, and points that differ from the above-described transparent electrode will be described in detail. For the elements that are the same as those of the above-described transparent electrode 200, the same reference numerals may be used.

Referring to FIG. 3, a first dielectric layer 111, a multi-layered metal layer 120, and a second dielectric layer 113 may be sequentially stacked on a substrate 100. The multi-layered metal layer 120 may further include an optical metal layer 125 spaced apart from a bridge metal layer 123 by the main metal layer 121. That is, the main metal layer 121 may be disposed between the bridge metal layer 123 and the optical metal layer 125.

The optical metal layer 125 may change a cutoff wavelength of the multi-layered metal layer 120. That is, the cutoff wavelength of the multi-layered metal layer 120 may be different from that of a double layer including the main metal layer 121 and the bridge metal layer 123. As described above, the refractive index of the optical metal layer 125 may be different from that of the double layer. Therefore, the difference in refractive index between the optical metal layer 125 and the double layer may cause the optical interference effect which may change the optical transmissivity. The cutoff wavelength may represent a wavelength of an infrared region at which the optical transmissivity of a layer is reduced to about 30%. The cutoff wavelength will be described in more detail later (see FIG. 5).

For example, the cutoff wavelength of the multi-layered metal layer 120 of FIG. 3 may be larger than that of the double layer. In this case, a wavelength range of infrared light that passes through the multi-layered metal layer 120 may become wider. This will be described in more detail later (see FIG. 5).

The optical metal layer 125 may include a metal material different from that of the main metal layer 121. However, the optical metal layer 125 may include the same metal material as the bridge metal layer 123, but the material of the optical metal layer 125 is not particularly limited. For example, the optical metal layer 125 may include Ag, Cu, Al, Au, Pt, Cr, Ni, Zn or Zr. A thickness of the optical metal layer 125 may be from about 0.1 nm to about 30 nm. By adjusting the metal material used in the optical metal layer 125 and the thickness thereof, the transmissivity of visual light or infrared right of a specific wavelength range may be increased.

### Embodiment 3

FIG. 4 is a cross-sectional view illustrating a transparent electrode 200 according to still another embodiment of the present invention. Regarding the present embodiment, detailed descriptions on technical features that overlap with those described above with reference to FIGS. 1 and 2 are not provided, and points that differ from the above-described transparent electrode will be described in detail. For the elements that are the same as those of the above-described transparent electrode 200, the same reference numerals may be used.

Referring to FIG. 4, a first dielectric layer 111, a cutoff wavelength control layer 130, a third dielectric layer 115, a multi-layered metal layer 120, and a second dielectric layer 113 may be sequentially stacked on a substrate 100. That is, the cutoff wavelength control layer 130 may be disposed between the first dielectric layer 111 and the multi-layered metal layer 120. The third dielectric layer 115 may be provided between the cutoff wavelength control layer 130 and the multi-layered metal layer 120. The above description of the thickness and material of the first dielectric layer 111 of FIG. 1 may be the same as that of the third dielectric layer 115.

The cutoff wavelength control layer 130 may change a cutoff wavelength of the transparent electrode 200. The refractive index of the cutoff wavelength control layer 130 may be different from the refractive indices of the first dielectric layer 111, the third dielectric layer 115 and the multi-layered metal layer 120. The difference in refractive index between the cutoff wavelength control layer 130 and layers adjacent thereto may cause the optical interference effect which may change the optical transmissivity.

FIG. 5 is a graph illustrating a change of the cutoff wavelength of the transparent electrode 200 in the embodiments of the present invention.

It may be understood from FIG. 5 that an optical transmissivity TR of the transparent 200 is changed as the material or the thickness of the multi-layered metal layer 120 or the cutoff wavelength control layer 130 is adjusted. The cutoff wavelength mentioned below may be defined as a wavelength of an infrared region at which the optical transmissivity TR is reduced to TR_{C}. For example, TR_{C} may be about 30%. In detail, in the case of the transmissivity of a first transparent electrode 200a, a wavelength of an infrared region at which the optical transmissivity TR is reduced to TR_{C} is W1. Here, W1 may be defined as the cutoff wavelength of the first transparent electrode 200a. Likewise, the cutoff wavelength of a second transparent electrode 200b is W2, and the cutoff wavelength of a third transparent electrode 200c is W3. The first to third transparent electrodes 200a to 200c may be any transparent electrodes according to the embodiments of the present invention (see FIGS. 1, 3 and 4).

The first transparent electrode 200a may be the transparent electrode 200 in which the cutoff wavelength control layer 130 is not provided as described above with reference to FIG. 1 or 3. Here, the cutoff wavelength W1 of the first transparent 200a may be relatively small. Provided that a wavelength of a boundary between visual light and infrared light is W0, the first transparent electrode 200a may easily transmit infrared light of a region between W0 and W1. The first transparent electrode 200a may reflect most of infrared light having a wavelength larger than the cutoff wavelength W1.

The third transparent electrode 200c may be the transparent electrode 200 of FIG. 4. That is, the third transparent electrode 200c may include the cutoff wavelength control layer 130 so that the optical transmissivity TR of the third transparent electrode 200c may be changed, and, as a result, the cutoff wavelength W3 of the third transparent electrode 200c may be shifted to a larger wavelength (W1→W3). The cutoff wavelength of the third transparent electrode 200c may be from about 3 μm to about 10 μm. The third transparent electrode 200c may easily transmit infrared light of a region between W0 and W3. Therefore, compared to the first transparent electrode 200a, the third transparent electrode 200c may transmit infrared light of a wider wavelength range. The third transparent electrode 200c may reflect most of infrared light having a wavelength larger than the cutoff wavelength W3. For example, provided that a wavelength of a boundary between infrared light and far-infrared light is W4, the third transparent electrode 200c may reflect most of far-infrared light, since W4 is larger than W3.

FIG. 6 is a conceptual diagram illustrating that the transparent electrode 200 enables directivity control with respect to transmission/cutoff of infrared light.

Referring to FIG. 6, the transparent electrode 200 according to the embodiments of the present invention may be disposed at a boundary between an indoor region IN and an outdoor region OUT (see FIGS. 1, 3 and 4). A third light L3 may be irradiated to the transparent electrode 200 in the outdoor region OUT. The third light L3 may be solar light. The third light L3 may include ultraviolet light, visual light, and infrared light. For example, the infrared light of the third light L3 may have a wavelength of about 3 μm or less.

The ultraviolet light and visual light of the third light L3 may pass through the transparent electrode 200. Furthermore, as described above with reference to FIG. 5, the transparent electrode 200 may easily transmit the infrared light of the third light L3 which has a specific wavelength, i.e., the infrared light having a wavelength of from W0 to W1 (see the first transparent electrode 200a), the infrared light having a wavelength of from W0 to W2 (see the second transparent 200b), or the infrared light having a wavelength of from W0 to W3 (see the third transparent electrode 200c).

A fourth light L4 may be irradiated to the transparent electrode 200 in the indoor region IN. The fourth light L4 may be far-infrared light in the indoor region IN. That is, the fourth light L4 may be far-infrared light having a long wavelength of at least W4 (see FIG. 5). For example, the wavelength W4 may be about 3 μm. As described above with reference to FIG. 5, the cutoff wavelengths W1 to W3 of the first to third transparent electrodes 200a to 200c may be smaller than the wavelength W4. Therefore, the fourth light L4 may be unable to pass through the transparent electrode 200 and may be reflected back to the indoor region IN. That is, the transparent electrode 200 according to the embodiments of the present invention may have a unidirectional characteristic with respect to transmission of infrared light as illustrated in FIG. 6.

As a result, the directivity with respect to transmission/cutoff of infrared light may be controlled by changing the optical transmissivity of the transparent electrode 200 by adjusting the material and thickness of the cutoff wavelength control layer 130. Furthermore, as described above, not only the cutoff wavelength control layer 130 but also the multi-layered metal layer 120 may be adjusted (e.g., adjustment of the materials and thicknesses of the main metal layer 121, the bridge metal layer 123, and the optical metal layer 125), so as to control the directivity with respect to transmission/cutoff of infrared light.

For example, the cutoff wavelength control layer 130 may include a metal selected from the group consisting of Ag, Cu, Al, Au, Pt, Cr, Ni, Zn and Zr or a dielectric material selected from the group consisting of ZnO, ITO, Al₂O₃, V₂O₅, TiO₂, SiO₂, SiN and ZrO₂. For another example, the cutoff wavelength control layer 130 may have a multi-layered structure including a plurality of layers each of which may include the metal or the dielectric material. A thickness of the cutoff wavelength control layer 130 may be from about 0.1 nm to about 50 nm.

### Embodiment 4

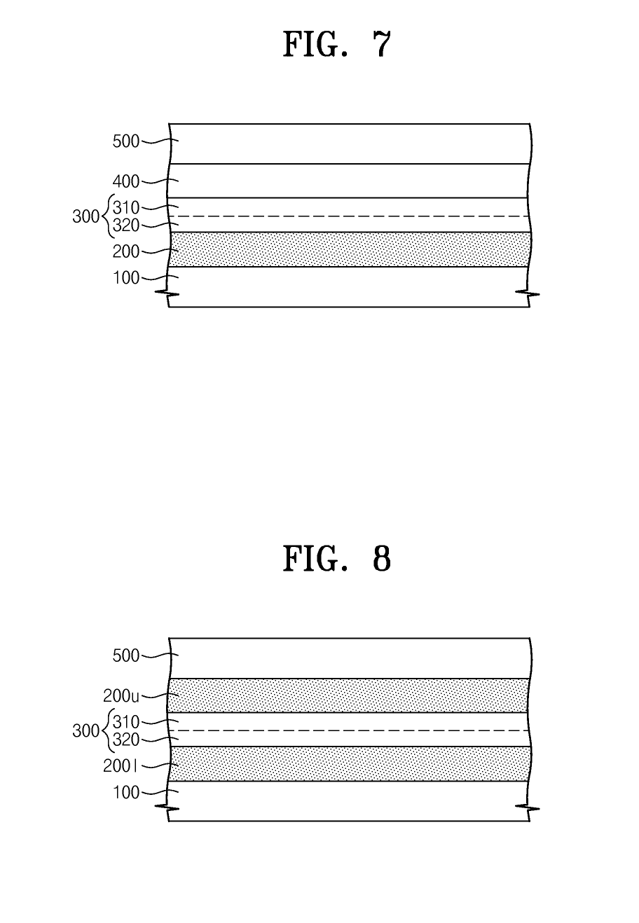

FIG. 7 is a cross-sectional view illustrating a solar cell according to an embodiment of the present invention.

Referring to FIG. 7, a transparent electrode 200, an optical absorption layer 300, and an upper electrode 400 may be sequentially stacked on a front substrate 100. A rear substrate 500 may cover the upper electrode 400.

The front substrate 100 may be a transparent substrate, and may include, for example, glass, polyether sulfone, polyethylene naphthalene (PEN), polyimide (PI), or acrylic resin. Description on the rear substrate 500 may be the same as the front substrate 100.

The transparent electrode 200 which is a lower electrode of the solar cell according to the present embodiment may be the same as the above-described transparent electrode 200 according to the embodiments of the present invention. However, the substrate of the above-described transparent electrode 200 may be replaced with the front substrate 100.

The upper electrode 400 may include a transparent conductive material. For example, the upper electrode 400 may include ITO, ZnO:Al, ZnO:Ga, ZnO:B or SnO₂. In another embodiment of the present invention, the transparent electrode 200 may be used as the upper electrode 400, but the upper electrode 400 is not particularly limited.

The optical absorption layer 300 may be disposed between the transparent electrode 200 and the upper electrode 400. The optical absorption layer 300 may be a single layer and/or a multilayer. The optical absorption layer 300 may include at least one of an amorphous silicon layer, an amorphous silicon germanium layer, a microcrystal silicon layer, and a microcrystal silicon germanium layer. The optical absorption layer 300 may include a first conductive layer 310 and a second conductive layer 320. The first conductive layer 310 may be an n-type doping layer, and the second conductive layer 320 may be a p-type doping layer. The first conductive layer 310 may be doped with group 5 elements such as phosphorus (P), arsenic (As), and antimony (Sb). The second conductive layer 320 may be doped with group 3 elements such as boron (B), gallium (Ga), and indium (In). Accordingly, a p-n junction may be formed between the first conductive layer 310 and the second conductive layer 320. Electric fields may be formed by the p-n junction. Alternatively, an intrinsic semiconductor layer not doped with impurities may be disposed between the first conductive layer 310 and the second conductive layer 320.

Solar light incident to the front substrate 100 may pass through the transparent electrode 200. The solar light that has passed through the transparent electrode 200 may be absorbed by the optical absorption layer 300 so as to form carriers (e.g., electrons or holes). The carriers may be moved to the first and second conductive layers 310 and 320 by the electric fields. For example, the electrons may be moved to the first conductive layer 310, and the holes may be moved to the second conductive layer 320. Therefore, a current may flow between the first conductive layer 310 and the second conductive layer 320.

The transparent electrode 200 may transmit visual light of the solar light at a high rate. However, a part of infrared light of the solar light may be unable to pass through the transparent electrode 200 and may be reflected (see FIG. 5). Therefore, the solar cell according to the present embodiment may be free from an issue of high reflection of visual light of a transparent solar cell. Furthermore, since the solar cell according to the present embodiment transmits visual light without reflecting the visual light, the solar cell may be used in windows and doors of buildings.

### Embodiment 5

FIG. 8 is a cross-sectional view illustrating a solar cell according to another embodiment of the present invention. Regarding the present embodiment, detailed descriptions on technical features that overlap with those described above with reference to FIG. 7 are not provided, and points that differ from the above-described solar cell will be described in detail. For the elements that are the same as those of the above-described solar cell, the same reference numerals may be used.

Referring to FIG. 8, a lower transparent electrode 2001, an optical absorption layer 300, and an upper transparent electrode 200u may be sequentially stacked on a front substrate 100. A rear substrate 500 may cover the upper electrode 200u.

The lower and upper transparent electrodes 2001 and 200u may be the same as the above-described transparent electrode 200 according to the embodiments of the present invention. However, the substrate of the above-described transparent electrode 200 may be replaced with the front substrate 100 or the rear substrate 500.

The transparent electrode 200 according to the embodiments of the present invention may be applied to the above-described transparent solar cell. In the case where a solar cell includes the transparent electrode 200, the solar cell may be capable of not only generating energy but also saving energy. The transparent electrode 200 may be applied to not only the solar cell of FIG. 8 but also amorphous silicon, a microcrystal silicon thin film, crystalline silicon, a CIGS thin film, a CdTe thin film, a dye-sensitized solar cell, and an organic solar cell.

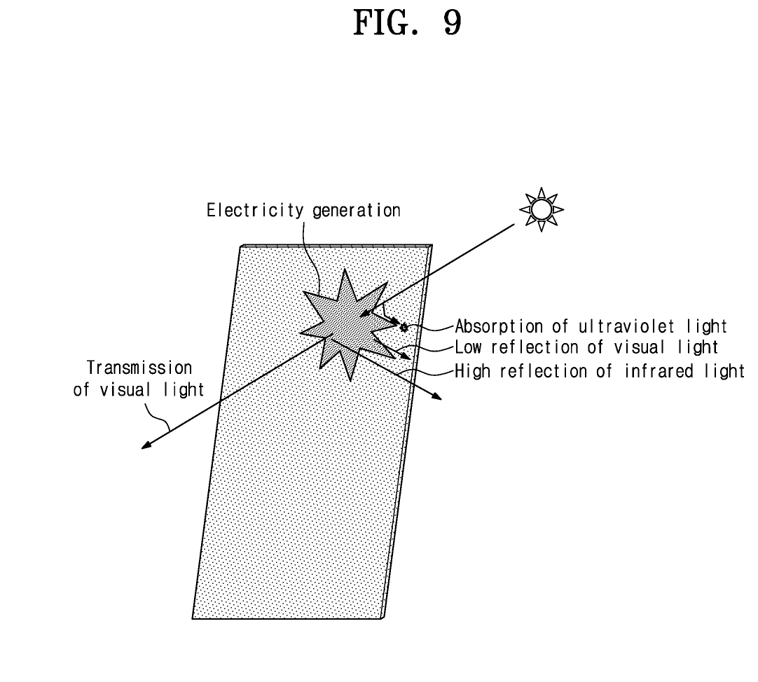

FIG. 9 is a conceptual diagram illustrating a function of a solar cell provided with the transparent electrode 200 in the embodiments of the present invention.

As described above, the transparent electrode 200 according to the embodiments of the present invention may have a high transmissivity of visual light with a wavelength of from about 400 nm to about 800 nm, but may have a low transmissivity of infrared light (particularly, far-infrared light) (see FIG. 6). The transmissivities of visual light and infrared light may be controlled by adjusting materials or thicknesses of a multi-layered metal layer and/or a cutoff wavelength control layer as described above.

Referring to FIG. 9, the solar cell provided with the transparent electrode 200 may have a high transmissivity of visual light by virtue of optical characteristics of the transparent electrode 200. Therefore, in the case where the solar cell according to the present invention is used in windows and doors, the issue of high reflection of window may be resolved. The solar cell may have a low transmissivity of infrared light by virtue of the optical characteristics of the transparent electrode 200. Therefore, the solar cell may reflect most of infrared light, particularly, far-infrared light emitted from an indoor area to the outside, thereby saving energy.

A part of visual light and ultraviolet light are absorbed by the optical absorption layer 300 so that the solar cell produces energy. As a result, the transparent solar cell according to the present invention may be applied to windows and doors of buildings to generate and save energy, so that a zero-energy building may be implemented.

The transparent electrode according to the present invention may increase the transmissivity of visual light and allows control of directivity with respect to transmission/cutoff of infrared light. Furthermore, since a multi-layered metal layer is used in the transparent electrode, the transparent electrode has excellent optical characteristics and a low sheet resistance. The solar cell including the transparent electrode of the present invention has a high transmissivity and a low degree of reflection of visual light so that visibility is secured, and energy may be saved by virtue of an insulating effect caused by cutoff of infrared light. Moreover, the solar cell may enable implementation of various colors to give an esthetic sense, and may be applied to large-size windows and doors of buildings.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A transparent electrode comprising:
a first dielectric layer and a multi-layered metal layer stacked on a substrate,
wherein the multi-layered metal layer comprises a main metal layer and a bridge metal layer,
wherein the main metal layer comprises an uneven surface,
wherein the bridge metal layer covers the uneven surface of the main metal layer, and comprises a top surface that is more even than the uneven surface of the main metal layer,
wherein a sheet resistance of the multi-layered metal layer is smaller than that of the main metal layer.

2. The transparent electrode of claim 1,
wherein the main metal layer comprises a recess region in the uneven surface,
wherein the bridge metal layer fills the recess region.

3. The transparent electrode of claim 2, wherein a distance between a bottom surface of the recess region and a bottom surface of the main metal layer is smaller than an average thickness of the main metal layer.

4. The transparent electrode of claim 1, wherein the sheet resistance of the multi-layered metal layer is from about 1 Ω/□ to about 2000 Ω/□.

5. The transparent electrode of claim 1, wherein a thickness of the main metal layer is from about 1 nm to about 50 nm, and a thickness of the bridge metal layer is from about 0.1 nm to about 15 nm.

6. The transparent electrode of claim 1,
wherein the main metal layer and the bridge metal layer comprise different metal materials,
wherein the main metal layer comprises Ag, Cu, Au, Pt or Al,
wherein the bridge metal layer comprises Ag, Cu, Al, Au, Pt, Cr, Ni, Zn or Zr.

7. The transparent electrode of claim 1, further comprising a second dielectric layer on the multi-layered metal layer, wherein the first and second dielectric layers individually comprise ZnO, Al₂O₃, V₂O₅, TiO₂, SiO₂, SiN, ZrO2, ITO, ZnO:Al, ZnO:Ga, ZnO:B, or SnO₂.

8. The transparent electrode of claim 1, wherein a thickness of the first dielectric layer is from about 0.1 nm to about 500 nm.

9. The transparent electrode of claim 1,
wherein the multi-layered metal layer further comprises an optical metal layer spaced apart from the bridge metal layer with the main metal layer interposed therebetween,
wherein a cutoff wavelength of the multi-layered metal layer is larger than that of a double layer comprising the main metal layer and the bridge metal layer,
wherein the cutoff wavelength is a wavelength of an infrared region at which an optical transmissivity of a layer is reduced to about 30% or lower.

10. The transparent electrode of claim 9,
wherein the main metal layer and the optical metal layer comprise different metal materials,
wherein the optical metal layer comprises Ag, Cu, Al, Au, Pt, Cr, Ni, Zn or Zr.

11. The transparent electrode of claim 9, wherein a thickness of the optical metal layer is from about 0.1 nm to about 50 nm.

12. The transparent electrode of claim 1, further comprising a cutoff wavelength control layer disposed between the first dielectric layer and the multi-layered metal layer, the cutoff wavelength control layer changing a cutoff wavelength of the transparent electrode,
wherein the cutoff wavelength is a wavelength of an infrared region at which an optical transmissivity of a layer is reduced to about 30% or lower,
wherein a refractive index of the cutoff wavelength control layer is different from refractive indices of the first dielectric layer and the multi-layered metal layer.

13. The transparent electrode of claim 12, wherein the cutoff wavelength control layer shifts the cutoff wavelength of the transparent electrode to a large wavelength.

14. The transparent electrode of claim 12, wherein the cutoff wavelength control layer comprises a metal selected from the group consisting of Ag, Cu, Al, Au, Pt, Cr, Ni, Zn and Zr or a dielectric material selected from the group consisting of ZnO, ITO, Al₂O₃, V₂O₅, TiO₂, SiO₂, SiN and ZrO₂.

15. The transparent electrode of claim 12, wherein a thickness of the cutoff wavelength control layer is from about 0.1 nm to about 50 nm.

16. The transparent electrode of claim 12, wherein the cutoff wavelength of the transparent electrode is from about 3 μm to about 10 μm.

17. A transparent electrode comprising:
a first dielectric layer and a multi-layered metal layer stacked on a substrate,
wherein the multi-layered metal layer comprises a main metal layer and a bridge metal layer stacked to directly contact each other,
wherein the main metal layer and the bridge metal layer have different refractive indices,
wherein a transmissivity of visual light with a wavelength of from about 400 nm to about 800 nm of the multi-layered metal layer is larger than that of the main metal layer.

18. The transparent electrode of claim 17,
wherein the main metal layer comprises an uneven surface and a recess region formed therein,
wherein the bridge metal layer fills the recess region.

19. The transparent electrode of claim 17,
wherein the multi-layered metal layer further comprises an optical metal layer spaced apart from the bridge metal layer with the main metal layer interposed therebetween,
wherein the bridge metal layer, the main metal layer, and the optical metal layer have different refractive indices,
wherein a cutoff wavelength of the multi-layered metal layer is larger than that of a double layer comprising the main metal layer and the bridge metal layer,
wherein the cutoff wavelength is a wavelength of an infrared region at which an optical transmissivity of a layer is reduced to about 30% or lower.

20. A solar cell comprising:
a first electrode and a second electrode on a substrate; and
an optical absorption layer disposed between the first electrode and the second electrode,
wherein at least one of the first electrode and the second electrode is a transparent electrode,
wherein the transparent electrode comprises a first dielectric layer and a multi-layered metal layer stacked,
wherein the multi-layered metal layer comprises a main metal layer and a bridge metal layer,
wherein the main metal layer comprises an uneven surface,
wherein the bridge metal layer covers the uneven surface of the main metal layer, and comprises a top surface that is more even than the uneven surface of the main metal layer,
wherein a sheet resistance of the multi-layered metal layer is smaller than that of the main metal layer.
